(19) United States
(12) Patent Application Publication
(10) Pub. No.: US 2008/0258286 A1
(43) Pub. Date: Oct. 23, 2008

(54) High Input/Output, Low Profile Package-On-Package Semiconductor System

(75) Inventors: Mark A. Gerber, Plano, TX (US); Kurt P. Wachtler, Richardson, TX (US); Abram M. Castro, Fort Worth, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/839,806

(22) Filed: Aug. 16, 2007

Related U.S. Application Data
(60) Provisional application No. 60/913,338, filed on Apr. 23, 2007.

(51) Int. Cl. H01L 23/02; H01L 21/00

(52) U.S. Cl. 257/686; 438/109; 257/E23.18

(57) ABSTRACT

A package-on-package system (100) has a first subsystem (191) interconnected with a second subsystem (192) by solder connectors (193). The first subsystem has an insulating, trace-laminated, sheet-like carrier (101), which is laminated (102) with an insulating trace-laminated frame (110) exposing a central portion (103) of the carrier. A first chip (160) is disposed in the central portion, with a second chip (170) on top; the height of the assembled chips approximates the frame height (111). Bondable contact pads (104) are in the central portion, and solderable terminals (121; pitch center-to-center 0.65 mm or less) on the frame. The second subsystem has a laminated substrate (194) with at least one chip (196) attached, and terminals (195) in locations matching the terminals (121) on the frame of the first subsystem. The terminals of both subsystems are interconnected with solder (193) of a higher reflow temperature than additional solder balls (190) for connecting to external parts.

### FIELD OF THE INVENTION

The present invention is related in general to the field of semiconductor devices and processes, and more specifically to structure and processes of a low profile package-on-package system with a device having a partial cavity substrate.

### DESCRIPTION OF THE RELATED ART

The long-term trend in semiconductor technology to double the functional complexity of its products every 18 months (Moore's “law”) has several implicit consequences. First, the higher product complexity should largely be achieved by shrinking the feature sizes of the chip components while holding the package dimensions constant; preferably, even the packages should shrink. Second, the increased functional complexity should be paralleled by an equivalent increase in reliability of the product. Third, the cost per functional unit should drop with each generation of complexity so that the cost of the product with its doubled functionality would increase only slightly.

As for the challenges in semiconductor packaging, the major trends are efforts to shrink the package outline so that the package consumes less area and less height when it is mounted onto the circuit board, and to reach these goals with minimum cost (both material and manufacturing cost). Recently, other requirements were added to this list, namely the need to have a high number of input/output terminals, and the need to design packages so that stacking of chips and/or packages becomes an option to increase functional density and reduce device thickness.

A successful strategy for stacking chips and packages can shorten the time-to-market of innovative products, which utilize available chips of various capabilities (such as processors and memory chips) and thus does not have to wait for a redesign of chips.

Recent applications especially for hand-held wireless equipments, combined with ambitious requirements for data volume and high processing speed, place new, stringent constraints on the size and volume of semiconductor components used for these applications. Consequently, the market place is renewing a push to shrink semiconductor devices both in two and in three dimensions, and this miniaturization effort includes packaging strategies for semiconductor devices as well as electronic systems.

### SUMMARY OF THE INVENTION

Applicants recognize the need for a fresh concept of achieving a coherent, low-cost method of assembling high lead count, fine pitch and low contour devices; the concept includes substrates and packaging methods for stacking devices. The goal includes vertically integrated semiconductor systems, which may include integrated circuit chips of functional diversity. The resulting system has excellent electrical performance, mechanical stability, and high product reliability. Further, it is a technical advantage that the fabrication method of the system is flexible enough to be applied for different semiconductor product families and a wide spectrum of design and process variations.

One embodiment of the present invention is a package-on-package system with a first subsystem interconnected with a second subsystem by solder connectors. The first subsystem has an insulating, trace-laminated, sheet-like carrier, which is laminated with an insulating trace-laminated frame exposing a central portion of the carrier. A first chip is disposed in the central portion, with a second chip on top; the height of the assembled chips approximates the frame height. Bondable contact pads are in the central portion, and solderable terminals (pitch center-to-center 0.65 mm or less) on the frame. The second subsystem has a laminated substrate with at least one chip attached, and terminals in locations matching the terminals on the frame of the first subsystem. The terminals of both subsystems are interconnected with solder of a higher reflow temperature than additional solder balls for connecting to external parts.

Another embodiment of the invention is a method for fabricating a semiconductor package-on-package system. In the method, a first subsystem is fabricated; a second subsystem is provided; the two subsystems are interconnected with solder connectors; and solder balls for connections to external parts are attached. On a strip of an insulating, sheet-like, trace-laminated carrier are sites for assembling semiconductor subsystems. A frame of an insulating, trace-laminated frame is laminated on each site so that a central portion of the carrier remains exposed. The frames have solderable terminals with a pitch center-to-center of 0.65 mm or less. Next, a first chip is disposed in each central portion, and a second chip is disposed on top of the first chip; bondable contact pads in the central carrier portion facilitate the assembly. The height of the assembled chips approximates the height of the frame. Each site may be encapsulated by filling the volume determined by the area of the central carrier portion and the height of the frame with encapsulation compound. Each individual site is then singulated from the strip, creating a plurality of first subsystems.

Next, a second subsystem is provided, which is a packaged semiconductor device with a substrate and terminals in locations matching the terminals of the frames, and at least one chip disposed on the substrate. Further, solder connectors are attached to the substrate terminals. In the next process step, a package-on-package system is fabricated by aligning the solder connectors on the terminals of a second subsystem with the terminals of a first subsystem, reflowing the solder connectors, and cooling to ambient temperature. The resulting height of the solder connectors is less than the pitch of the terminals.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWING

FIG. 1 illustrates a schematic cross section of an embodiment of the invention, a package-on-package semiconductor system including a first and a second subsystem, wherein the first subsystem has a frame laminated on a carrier to provide the space for the assembling a vertical semiconductor chip set.

### DETAILED DESCRIPTION OF THE PREFERRED EMBODIMENTS

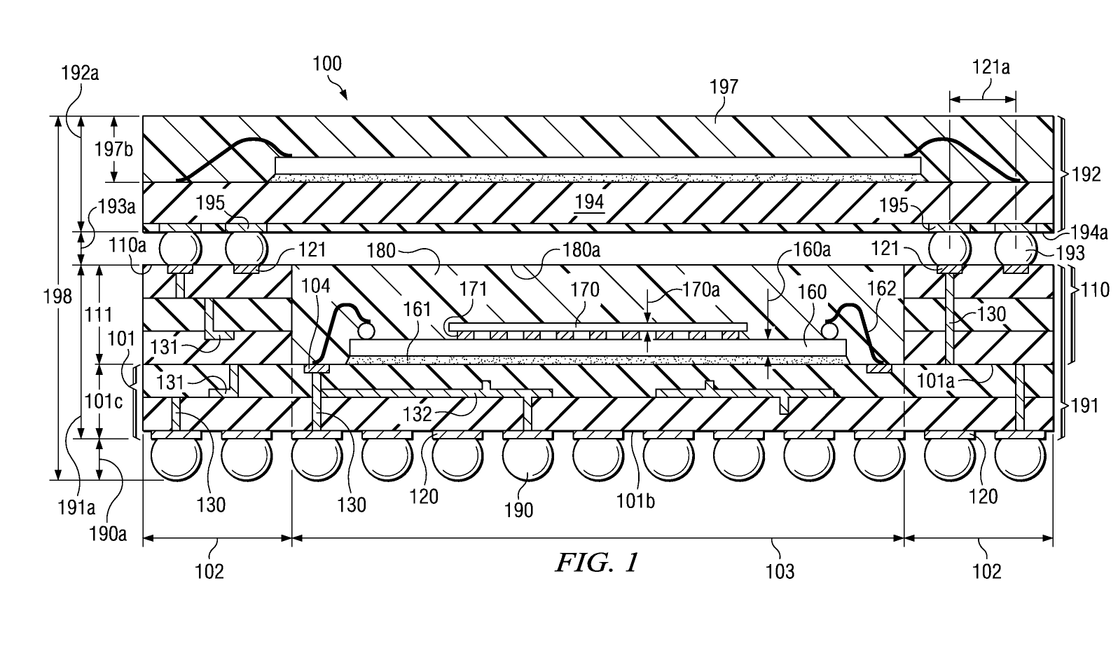

FIG. 1 illustrates an embodiment of the invention, a semiconductor package-on-package system generally designated 100. System 100 includes first subsystem 191 and second subsystem 192; the vertical integration of subsystem 191 and subsystem 192 is accomplished by solder connectors 193, and the connection to external parts is provided by solder balls 190.

As FIG. 1 shows, the first subsystem 191 includes an insulating sheet-like carrier 101, which has a first surface 101a and a second surface 101b. Carrier 101 has a laminated structure made of alternating layers of insulating material (such as compliant or stiff polymers, or ceramics) and metallic traces (such as copper). For 2 to 4 layers of metallic traces in carrier 101, the preferred height 101c is about 0.15 mm.

First surface 101a has a central portion 103 with an area large enough to assemble the semiconductor chips, and a peripheral portion 102, which is shown in FIG. 1 to surround the central portion 103 on all sides. The central portion 103 has a plurality of contact pads 104, which are bondable for wire bonds and flip-chip bonds. Preferably, pads 104 are made of copper with a flash of gold on the surface. As depicted in FIG. 1, there are terminals 120 on second carrier surface 101b, which can be contacted by solder alloys such as tin-based solders. In order to facilitate solderability, terminals 120 are preferably made of copper with surface layers of nickel and gold, or nickel and palladium.

Subsystem 191 further includes an insulating frame 110, which has a laminated structure made of alternating layers of insulating material (such as compliant or stiff polymers, or ceramics) and metallic traces (such as copper). Frame 110 is laminated onto carrier 101 along sections 102 of the carrier first surface 101a. Consequently, the widths of the peripheral portions 102 of carrier surface 101a are determined by the insulating frame 110. Frame 110 exposes the central portion 103 and the bondable contact pads 104. As FIG. 1 shows, frame 110 has a height 111 and a third surface 110a; height 111 is preferably about 0.30 mm. Surface 110a has a plurality of solderable terminals 121, which have a pitch 121a center-to-center. The solderable terminals 121 are preferably made of copper with surface layers of nickel and gold, or nickel and palladium.

The sum of the carrier height 101c and the frame height 111 results in a height 191a of first subsystem 191 of about 0.45 mm. With suitable assembly of the semiconductor chips (see below), height 191a can be reduced further.

The market for semiconductor products drives the trend to increase the numbers of terminals 121 (input/output terminals) and thus drives the requirement to shrink the terminal pitch 121a. Shrinkage of pitch 121a further drives the size reduction of solder connectors 193, which in turn supports the reduction of the system outline. The invention provides the possibility to shrink pitch 121a from 0.65 mm to 0.5 mm and further to 0.40 mm.

Frame 110, like carrier 101, has a laminated structure made of alternating layers of insulating material (such as polymers or ceramics) and metallic traces (such as copper). For frame 110 and carrier 101, FIG. 1 depicts schematically portions of conductive vertical vias 130 and conductive horizontal traces 131, for carrier 101 also traces 132 across the central surface portion 103 of the carrier.

As illustrated in FIG. 1, a first semiconductor chip 160 is disposed in the central portion 103 of carrier 101. In the example shown, chip 160 is mechanically attached to the surface 101a of carrier 101 by an adhesive 161, and electrically connected by bonding wires 162 to contact pads 104. Chip 160 has a first height 160a. With efforts to backgrind chip 160 further, chip height 160a may be reduced, and by using bonders with programs to keep the loop height of wire 162 low, the assembly of chip 160 can be kept at a low profile.

As further illustrated in FIG. 1, a second chip 170 is disposed on top of first chip 160. Second chip 170 may have a size different from the size of first chip 160, or it may have the same size, and also may have a second height 170a different from first height 160a, or it may have the same height. In the example shown, second chip 170 is mechanically and electrically flip-attached to first chip 160 by bumps 171.

Alternatively, the first chip may be flipped onto the carrier, and the second chip, adhesively attached to the first chip, may be wire bonded to the carrier. For this alternative, the first chip has metal bumps, which are aligned with and attached to contact pads on the first surface of the carrier; further, the wires of the second chip are bonded to additional contact pads on the first surface.

It is preferred to have an encapsulation compound protect the chips and the connections of the first subsystem. In FIG. 1, encapsulation compound 180, such as an epoxy-based molding compound, fills the volume determined by the area of the central carrier portion 103 and the height 111 of the frame 110.

The sum of first height 160a, second height 170a, loop height of wire bond 162, and height of the bumps 171 approximates the height 111 of frame 110. In FIG. 1, the sum is smaller than the frame height 111; consequently, the surface 180a of encapsulation compound 180 is preferably coplanar with surface 110a of frame 110. In other devices, the sum may be slightly greater than the frame height so that the surface of the encapsulation compound slightly surpasses the frame surface 110a.

The package-on-package system 100 depicted in FIG. 1 has a second subsystem 192, which has an insulating substrate 194 made from a material such as laminated plastic, ceramic, or FR-4 board. Substrate 194 has a thickness 194b and a fourth surface 194a, which faces third surface 110a. On fourth surface 194a are terminals 195 in locations matching the terminals 121 on the third surface 110a. Preferably, terminals 195 are made of copper and have a solderable surface such as gold flash, or layers of nickel and gold, or nickel and palladium.

Subsystem 192 has at least one semiconductor chip 196 disposed on substrate 194; alternatively, subsystem 192 may have one or more stacks of semiconductor chips. In FIG. 1, chip 196 is attached to substrate 194 by an adhesive and has wire bonds as electrical connections; alternatively, the chip (or the stack of chips) may be disposed by flip-chip technology. It is preferred that chip 196 and its connections are packaged in encapsulation material 197, for instance a molding compound; in FIG. 1, the thickness of encapsulation 197 is designated 197b; it includes the thickness of chip 196 (or the stack of chips).

The sum of substrate thickness 194b and encapsulation thickness 197b represents the thickness 192a of subsystem 192. Together with connector thickness 193a, the resulting thickness is between 0.7 and 0.8 mm.

Solder connectors 193 interconnect the terminals 121 on the third surface 110a and the matching terminals 195 on the fourth surface 194a. Connectors 193 have a height 193a, which is less than the pitch 121a of the terminals. For devices with pitch 121a of 0.65 mm, height 193a is less than 0.65 mm; for devices with pitch 121a of 0.50 mm, height 193a is less than 0.50 mm; and for devices with pitch 121a of 0.40 mm, height 193a is less than 0.40 mm. Solder connectors 193 are preferably tin-based and have preferably a reflow temperature higher than the reflow temperature of solder balls 190 attached to the terminals 120 on the second surface 101b of the carrier of the first subsystem.

In addition, the sum of thickness 191a of subsystem 191, thickness 192a of subsystem 192, height 193a of connectors 193, and height 190a of solder balls 190 determines the overall thickness 198 of the package-on-package system 100. For many systems, it is 1.4 mm; for flip-chip subsystems, the overall thickness 198 is approaching 1.0 mm. The reduction of thickness is facilitated by reducing the height 111 of frame 110. In this effort, it is acceptable to reduce height 110 so much that surface 180a of encapsulation compound 180 is no longer coplanar with frame surface 110a, but slightly bulging over surface 110a; the height 193a of solder balls 193 provides for some distance between the bulging compound surface and substrate surface 194a of the second subsystem.

Another embodiment of the invention is a method for fabricating a semiconductor package-on-package system 100, especially a vertically integrated system. The method is based on fabricating a first subsystem 191, providing a second subsystem 192, interconnecting the two subsystems with solder connectors 193, and (optionally) attaching solder balls 190 for connections to external parts.

For fabricating the first subsystem, the method starts with the step of providing a strip 101 of an electrically insulating sheet-like carrier, which has a first and a second surface (101a and 101b, respectively). The strip may be made of ceramic, or compliant or stiff polymer, or similar insulating material. The strip includes conductive vertical vias 130 and conductive horizontal traces 131 and 132; the carrier further having solderable terminals 120 on the second surface.

The sites for assembling semiconductor subsystems are on the first surface of the strip. Each site includes a central portion 103 with an area sized for assembling semiconductor chips, and a peripheral portion 102 surrounding the central portion. Contact pads 104 suitable for wire bonding or flip-chip bonding are on the central surface portions.

Frames 110 made of insulating material are then provided, which have conductive vertical vias 130 and conductive horizontal lines 131; preferably, the frames have a laminated structure. Each frame has further a height 111 and a third surface 110a with solderable terminals 121; the terminals are located to have a certain pitch 121a center-to-center. A frame is laminated to each peripheral portion 102 of the assembly sites, exposing the respective central portion 103 of the site.

Next, a plurality of first chips 160 is provided; the chips have a first height 160a. A first chip is then assembled to the central portion of each site, and the chip is electrically connected to contact pads in the central portion. Next, a plurality of second chips 170 is provided; the chips have a second height 170a. A second chip is assembled on top of each first chip and, if required, electrically bonded to selected contact pads in the central carrier portion. The sum of the first and the second chip heights approximates the frame height.

In the next process step, each site is encapsulated by using encapsulation material 180 such as molding compound to fill the volume determined by the area of the central surface portion and the height of the frame. After polymerizing (hardening) the encapsulation material, each individual assembly site is singulated (preferably by sawing) from the strip, thus creating a plurality of first subsystems 191. Each subsystem includes a strip portion as first substrate.

For providing the second subsystem 192, the method prefers a packaged semiconductor device with the following features: The device has a second insulating substrate 194 with a fourth surface 194a; on this surface are solderable terminals 195 in locations, which match the terminals 121 on the third surface 110a of the first subsystems. The device further has at least one semiconductor chip 196 (or stack of chips) disposed on the second substrate. The at least one chip is preferably encapsulated in molding compound. In addition, solder connectors 193 of a first reflow temperature are attached to the terminals 195 on the fourth surface.

Next, for interconnecting the first subsystem 191 and the second subsystem 192, solder connectors 193 are attached to the terminals 195 on the fourth surface 194a of the second subsystem; then, they are aligned with the matching terminals 121 on the third surface 110a of the first subsystem. The temperature of the subsystems is increased to the melting temperature of the solder in order to reflow the connectors 193 and to interconnect the third and fourth surfaces. Thereafter, the temperature is cooled to ambient temperature so that the solder connectors have a height 193a less than the pitch 121a of the terminals.

Finally, solder balls 190 may be attached to the terminals 120 on the second surface 101b. The solder alloy of balls 190 has a second reflow temperature lower than the first reflow temperature of connectors 193; consequently, connectors 193 will not re-melt, when balls 190 are attached or, at a later time, reflowed once more to connect to an external part.

Alternatively, terminals 120 may be used as lands for pressure contacts, without solder balls 190. In this alternative, the package-on-package system 100 exhibits its minimum height 198.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip, discrete or integrated circuit, and the material of the semiconductor chip may comprise silicon, silicon germanium, gallium arsenide, or any other semiconductor or compound material used in integrated circuit manufacturing.

As another example, the process step of encapsulating can be omitted when the integration of the system has been achieved by flip-chip assembly.

It is therefore intended that the appended claims encompass any such modifications or embodiment.

We claim:

1. A semiconductor package-on-package system comprising:
a first subsystem, a second subsystem, interconnected with solder connectors;
the first subsystem including:
an insulating sheet-like carrier having a first surface and a second surface, the first surface having a central portion with an area and a peripheral portion;
an insulating frame having a height and a third surface, the frame laminated to the peripheral portion of the carrier and exposing the central portion;
a first chip, having a first height, disposed in the central portion;
a second chip, having a second height, disposed on top of the first chip, the sum of the first and second heights approximating the frame height;
the carrier including conductive vertical vias and conductive horizontal traces, including traces across the central portion, bondable contact pads on the central surface portion, and solderable terminals on the second surface; and
the frame including conductive vertical vias and conductive horizontal traces, and solderable terminals on the third surface, the terminals having a pitch center-to-center;
the second subsystem including:
an insulating substrate having a fourth surface facing the third surface;
solderable terminals on the fourth surface in locations matching the terminals on the third surface;
at least one semiconductor chip disposed on the second substrate; and
the solder connectors interconnecting the terminals on the third and the fourth surface having a height less than the pitch of the terminals.

2. The system according to claim 1 wherein the solder connectors have a first reflow temperature.

3. The system according to claim 2 further having solder balls attached to the terminals on the second surface, the solder balls having a second reflow temperature lower than the first reflow temperature.

4. The system according to claim 1 wherein the disposition of the first and the second chip include mechanical attachment with adhesives and electrical connection with flip-chip or bonding wires.

5. The system according to claim 1 further including encapsulation compound for the first subsystem, the compound filling the volume determined by the area of the central carrier portion and the height of the frame, protecting the chips and the electrical connections.

6. The system according to claim 1 wherein the pitch center-to-center of the terminals on the third and fourth surfaces is 0.65 mm or less, and the pitch center-to-center of the terminals on the second surface is 0.4 mm or less.

7. The system according to claim 1 wherein the pitch center-to-center of the terminals on the third and fourth surfaces is about 0.50 mm.

8. The system according to claim 1 wherein the pitch center-to-center of the terminals on the third and fourth surfaces is about 0.40 mm.

9. The system according to claim 1 wherein the contact pads on the central surface portion are used by flip-chip and wire bonds to connect to the first and second chips disposed in the central portion.

10. A method for fabricating a semiconductor package-on-package system, comprising the steps of:
fabricating a first subsystem comprising the steps of:
providing a strip of an insulating sheet-like carrier having a first and a second surface, and including conductive vertical vias and conductive horizontal traces; the carrier further having solderable terminals on the second surface; the first surface having sites for assembling semiconductor subsystems, each site including a central portion having an area and a peripheral portion, with bondable contact pads on the central surface portions;
providing a plurality of insulating frames having conductive vertical vias and conductive horizontal lines, each frame further having a height and a third surface with solderable terminals having a pitch center-to-center;
laminating a frame to each peripheral portion of the assembly sites, exposing the respective central portion;
providing a plurality of first chips having a first height;
assembling a first chip to the central portion of each site, while electrically connecting the first chip to contact pads in the central portion;
providing a plurality of second chips having a second height;
assembling a second chip on top of each first chip and electrically bonding selected connections to contact pads in the central portion so that the sum of the first and the second chip height approximates the frame height;
encapsulating each site by filling the volume determined by the area of the central surface portion and the height of the frame with encapsulation compound; and
singulating each individual site from the strip, thus creating a plurality of first subsystems, each including a strip portion as first substrate;
providing a second subsystem comprising a packaged semiconductor device including:
a second insulating substrate having a fourth surface with solderable terminals in locations matching the terminals on the third surface of the first subsystems;
at least one semiconductor chip disposed on the second substrate; and
solder connectors of a first reflow temperature attached to the terminals on the fourth surface;
fabricating a package-on-package system comprising the steps of:
aligning the solder connectors on the terminals on the fourth surface of a second subsystem with the terminals on the third surface of a first subsystem;
increasing the temperature to reflow the solder connectors and interconnect the third and fourth surfaces; and
cooling the temperature to ambient temperature so that the solder connectors have a height less than the pitch of the terminals.

11. The system according to claim 11 further including the step of attaching solder balls to the terminals on the second surface, the connectors having a second reflow temperature lower than the first reflow temperature.
